(19) United States
(12) Patent Application Publication
(10) Pub. No.: US 2015/0030771 A1
(43) Pub. Date: Jan. 29, 2015

(54) COBALT SUBSTRATE PROCESSING SYSTEMS, APPARATUS, AND METHODS

(71) Applicant: Applied Materials, Inc., Santa Clara, CA (US)

(72) Inventors: Avgerinos V. Gelatos, Redwood City, CA (US); Bhushan Zope, Santa Clara, CA (US); Bo Zheng, Saratoga, CA (US)

(21) Appl. No.: 14/337,836

(22) Filed: Jul. 22, 2014

Related U.S. Application Data
(60) Provisional application No. 61/857,794, filed on Jul. 24, 2013.

(51) Int. Cl. C23C 16/02; C23C 18/16; C23C 18/32; C23C 16/06; C23C 16/46

(52) U.S. Cl. CPC C23C 16/0272; C23C 16/06; C23C 16/46; C23C 18/32; C23C 18/1601
USPC 427/251; 118/719; 427/250

(57) ABSTRACT

Electronic device processing systems including cobalt deposition are described. One system includes a mainframe having a transfer chamber and at least two facets, and one or more process chambers adapted to carry out a metal reduction or metal oxide reduction process and possibly an annealing processes on substrates, and one or more deposition process chambers adapted to carry out a cobalt deposition process. Other systems includes a transfer chamber, one or more load lock process chambers coupled to the transfer chamber that are adapted to carry out a metal reduction or metal oxide reduction process. Additional methods and systems for cobalt deposition processing of substrates are described, as are numerous other aspects.

### RELATED APPLICATIONS

This application claims priority from U.S. Provisional Patent Application Ser. No. 61/857,794, filed Jul. 24, 2013, titled “COBALT SUBSTRATE PROCESSING SYSTEMS, APPARATUS, AND METHODS” (Attorney Docket No. 20974/USAL), which is hereby incorporated by reference herein in its entirety.

### FIELD

The present invention relates to electronic device manufacturing, and more specifically to apparatus, systems, and methods for processing of substrates.

### BACKGROUND

Conventional electronic device manufacturing systems may include multiple process chambers arranged around a mainframe having a transfer chamber and one or more load lock chambers. These systems may employ a transfer robot, which may be housed in the transfer chamber, for example. The robot may be a selectively compliant articulated robot arm (SCARA) robot or the like and may be adapted to transport substrates between the various chambers and one or more load lock chambers. For example, the transfer robot may transport substrates from process chamber to process chamber, from load lock chamber to process chamber, and vice versa.

Processing is generally carried out in multiple tools where the substrates travel between tools in substrate carriers (e.g., Front Opening Unified Pods or FOUPs). However, such configurations tend to be relatively expensive.

Accordingly, systems, apparatus, and methods having improved efficiency and/or capability in the processing of substrates are desired.

### SUMMARY

In one aspect, an electronic device processing system is provided. The electronic device processing system includes a mainframe having at least one transfer chamber, and at least two facets, a first process chamber coupled to at least one of the at least two facets and adapted to carry out a metal reduction process or metal oxide reduction process on substrates, and at least one deposition process chamber coupled to another one of the at least two facets and adapted to carry out a cobalt chemical vapor deposition process on substrates.

In one aspect, a method of processing substrates within an electronic device processing system is provided. The method includes providing a mainframe having at least one transfer chamber and at least two facets, at least one process chamber coupled to at least one of the at least two facets, and at least one deposition process chamber coupled to at least another one of the at least two facets, carrying out a metal reduction process or metal oxide reduction process on substrates in the at least one process chamber, and carrying out a cobalt chemical vapor deposition process on substrates in the at least one deposition process chamber.

In another aspect, an electronic device processing system is provided. The electronic device processing system includes a mainframe having a transfer chamber and at least two facets, at least one deposition process chamber coupled to at least one of the at least two facets and adapted to carry out a cobalt chemical vapor deposition process on substrates, and a load lock apparatus coupled to at least another facet of the at least two facets, the load lock apparatus adapted to carry out a metal reduction or metal oxide reduction process on substrates.

In another method aspect, a method of processing substrates within an electronic device processing system is provided. The method includes providing a mainframe having a transfer chamber and at least two facets, providing one or more deposition process chambers coupled to at least one or the at least two facets, providing a load lock apparatus having one or more load lock process chambers coupled to another one of the at least two facets, carrying out a metal reduction or metal oxide reduction process on substrates in the one or more load lock process chamber, and carrying out a cobalt chemical vapor deposition process on substrates in at least one of the one or more deposition process chambers.

Numerous other aspects are provided in accordance with these and other embodiments of the invention. Other features and aspects of embodiments of the present invention will become more fully apparent from the following detailed description, the appended claims, and the accompanying drawings.

### BRIEF DESCRIPTION OF THE DRAWINGS

FIG. 1A illustrates a schematic top view of an electronic device processing system according to embodiments.

FIG. 1B illustrates a schematic top view of another electronic device processing system including multiple interconnected mainframes according to embodiments.

FIG. 2 illustrates a schematic top view of another electronic device processing system including one or more cobalt deposition process chambers with a carousel according to embodiments.

FIG. 3 illustrates a schematic top view of another electronic device processing system according to embodiments.

FIG. 4A illustrates a schematic top view of another electronic device processing system including one or more cobalt deposition chambers in a carousel according to embodiments.

FIG. 4B illustrates a cross-sectioned side view of a load lock apparatus taken along section line 4B-4B of FIG. 4A according to embodiments.

FIG. 5 illustrates a flowchart depicting a method of processing substrates according to embodiments.

FIG. 6 illustrates another flowchart depicting an alternative method of processing substrates according to embodiments.

FIG. 7 illustrates another flowchart depicting an alternative method of processing substrates according to embodiments.

### DESCRIPTION

Electronic device manufacturing may desire very precise processing, as well as rapid transport of substrates between various locations.

According to one or more embodiments of the invention, an electronic device processing system adapted to provide deposition (e.g., chemical vapor deposition—CVD) of cobalt (Co) are provided. In some embodiments, electronic device processing systems (e.g., a semiconductor component processing tool) adapted to provide both deposition (e.g., chemical vapor deposition—CVD) of cobalt (Co) and carry out a metal oxide reduction process on substrates are provided. The systems and methods described herein may provide efficient and precise processing of substrates having cobalt deposition.

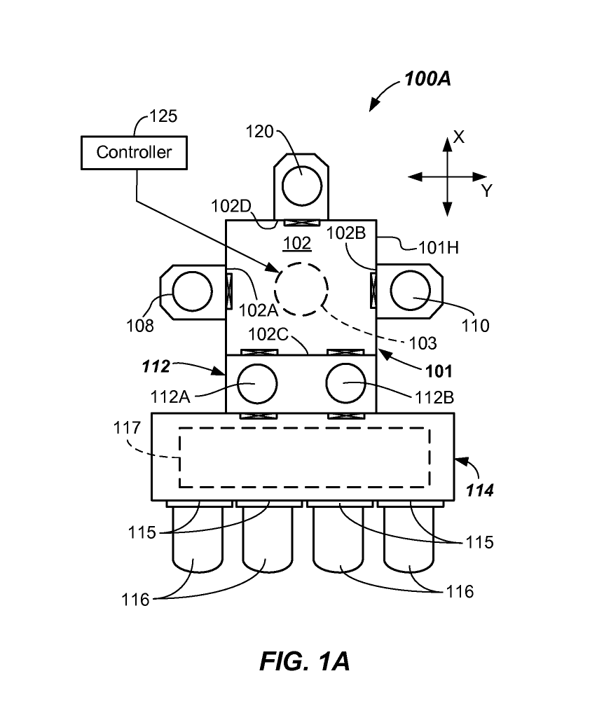

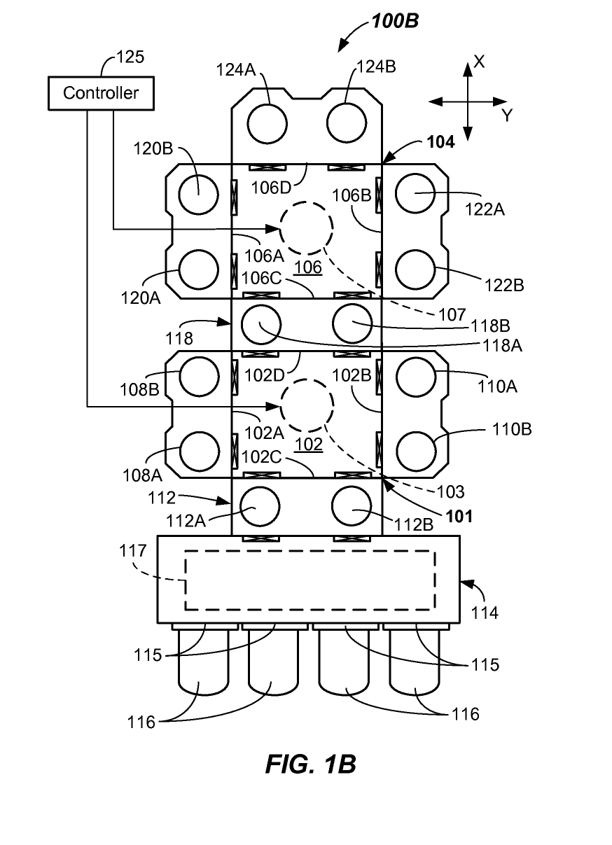

Further details of example method and apparatus embodiments of the invention are described with reference to FIGS. 1A-6 herein.

FIG. 1A is a schematic diagram of a first example embodiment of an electronic device processing system 100A according to embodiments of the present invention. The electronic device processing system 100A may include a mainframe 101 including a mainframe housing 101H having housing walls defining a transfer chamber 102. A multi-arm robot 103 (shown as a dotted circle) may be at least partially housed within the transfer chamber 102. The first multi-arm robot 103 may be configured and adapted to place or extract substrates (e.g., silicon wafers which may have a pattern therein) to and from destinations via operation of the arms of the multi-arm robot 103.

Multi-arm robot 103 may be any suitable type of robot adapted to service the various chambers coupled to and accessible from the transfer chamber 102, such as the robot disclosed in PCT Pub. No. WO2010090983, for example. Other types of robots may be used. In some embodiments, an off-axis robot may be used that has a robot configuration that can operate to extend an end effector other than radially towards or away from a shoulder rotational axis of the robot, which is generally centered at the center of the transfer chamber 102.

The transfer chamber 102 in the depicted embodiment may be generally square or slightly rectangular in shape and may include a first facet 102A, a second facet 102B, a third facet 102C, and a fourth facet 102D. The first facet 102A may be opposite the second facet 102B. The third facet 102C may be opposite the fourth facet 102D. The first facet 102A, second facet 102B, a third facet 102C, and fourth facet 102D may be generally planar and entryways into the chambers may lie along the respective facets 102A-102D.

The destinations for the multi-arm robot 103 may be a first process chamber 108 coupled to the first facet 102A and which may be configured and operable to carry out a pre-clean or a metal or metal oxide removal process, such as a copper oxide reduction process on the substrates delivered thereto. The metal or metal oxide removal process may be as described in US Pub. No. 2009/0111280; and 2012/0289049; and U.S. Pat. Nos. 7,972,469; 7,658,802; 6,946,401; 6,734,102; and 6,579,730, for example, which are hereby incorporated by reference herein. One or more pre-clean processes may be carried out therein, which may be a precursor processes to a cobalt deposition process. The destinations for the multi-arm robot 103 may also be a second process chamber 110 that may be generally opposed from the first chamber 108. The second process chamber 110 may be coupled to the second facet 102B and may be configured and adapted to carry out high-temperature reducing anneal process on the substrates in some embodiments. The high-temperature reducing anneal processes may be as described in US Pub. No. 2012/0252207; and U.S. Pat. Nos. 8,110,489, and 7,109,111, for example, the disclosures of which are hereby incorporated by reference herein. The annealing process may take place at a temperature of about 400° C. or more.

Substrates may be received from a factory interface 114 (otherwise referred to as an Equipment Front End Module (EFEM), and also exit the transfer chamber 102, to the factory interface 114, through a load lock apparatus 112. The load lock apparatus 112 may include one or more load lock chambers 112A, 112B. load lock apparatus 112 may include one or more load lock chambers at multiple vertical levels in some embodiments. In some embodiments, each vertical level may include side-by-side chambers being located at first level and a second level at a different level than the first level (either above or below). Side-by-side chambers may be at the same vertical level at the lower level and at a same vertical level at the upper level. For example, chambers included as load lock chambers 112A, 112B (e.g., single wafer load locks (SWLL)) may be provided at a lower vertical level in the load lock apparatus 112. The load locks (e.g., single wafer load locks (SWLL)) may each have a heating platform/apparatus to heat the substrate to greater than about 200° C., such that a degassing process may be carried out on incoming substrates before they are passed into the transfer chamber 102 from the factory interface 114 as described in U.S. patent application Ser. No. 14/203,098 filed Mar. 10, 2014, and U.S. Provisional Patent Application No. 61/786,990 filed Mar. 15, 2013, for example, the disclosures of which are hereby incorporated by reference herein.

The load lock apparatus 112 may include second side-by-side chambers (not shown) at an upper vertical level in the load lock apparatus 112, at a position above the lower level. In some embodiments, the load lock apparatus 112 includes a first chamber or chamber set adapted to carry out a degas process and allow pass through at a first level, and second chamber or chamber set adapted to carry out a cool-down process at second level thereof, wherein the first and second levels are different levels. In other embodiments, second side-by-side chambers in the load lock apparatus 112 may be used to carry out a pre-clean or oxide reduction process on the substrates, such as a metal oxide reduction process on the substrates as described in US as described in U.S. patent application Ser. No. 14/203,098 filed Mar. 10, 2014. Thus, in some embodiments, additional stations to accomplish a pre-clean process, a metal or metal oxide reduction process, or other processes such as cool down on the substrates may be provided in the load lock apparatus 112 in addition to those provided at the first process chamber 108 and second process chamber 110. The additional stations to accomplish a metal or metal oxide reduction process or other processes on the substrates may be provided in the load lock apparatus 112 in substitution to those provided at the first process chamber 108 in some embodiments, such that second process chamber 110 may be used for other processes, such as annealing, cooling, temporary storage, or the like.

The factory interface 114 may be any enclosure having one or more load ports 115 that are configured and adapted to receive one or more substrate carriers 116 (e.g., front opening unified pods or FOUPs) at a front face thereof. Factory interface 114 may include a suitable exchange robot 117 (shown dotted) of conventional construction within a chamber thereof. The exchange robot 117 may be configured and operational to extract substrates from the one or more substrate carriers 116 and feed the substrates into the one or more load lock chambers 112A, 112B (e.g., single wafer load locks (SWLL)), such as may be provided at a lower vertical level in the load lock apparatus 112. Load lock apparatus 112 may be could to the third facet 102C.

The mainframe housing 101H may include another process chamber coupled to another facets, such as the fourth facet 102D, such as a deposition process chamber 120 that is accessible and serviceable by multi-arm robot 103 from the transfer chamber 102. Deposition process chamber 120 may be configured and adapted to carry out a deposition process on substrates received thereat.

For example, the deposition process chamber 120 may carry out a cobalt (Co) chemical vapor deposition (CVD) process on the substrates. Co deposition CVD processes are taught in US Pub. No. 2012/0252207, for example, which is hereby incorporated by reference herein. Other processes may also be carried out therein, such as cobalt plasma vapor deposition (cobalt PVD). In some embodiments, the transfer chambers 102 may be operated at a vacuum. In others, the transfer chamber 102 may receive an insert gas therein, such as Argon (Ar). Argon gas may be provided by any suitable conventional delivery system.

Substrates as used herein shall mean articles used to make electronic devices or circuit components, such as silica-containing wafers, patterned wafers, or the like.

In some embodiments, the substrates may have previously undergone a plasma vapor deposition (PVD) process (e.g., a PVD Co deposition and/or a PVD CO flash process). The PVD CO flash process may function to provide a thin seed layer on the substrate. In some embodiments, a PVD process may be carried out before the CVD cobalt deposition process, and a separate PVD process may be carried out after the CVD cobalt deposition process, as well. In some embodiments, the PVD process may be carried out in an entirely different tool separate from the electronic device processing system 100A. However, in some embodiments, the PVD cobalt deposition may take place at one or more of the deposition process chamber coupled to the housing 101H.

For example, at least one deposition process chamber may be adapted to carry out a plasma vapor deposition process on the substrates. For example, process chamber 110 may be used for plasma vapor deposition process. Annealing may take place at another process chamber coupled to the housing 101H, or in a separate tool. In some embodiments, one or more than one process chamber may be adapted to carry out a cobalt CVD process. For example, both process chamber 110 and deposition process chamber 120 may be used to carry out cobalt CVD process in some embodiments. Other polygonal mainframe shapes may be used, such as pentagonal, hexagonal, heptagonal, octagonal, and the like, to enable addition of other process chambers or deposition process chambers.

The transfer chamber 102 may include slit valves at the ingress/egress to the various process chambers 108, 110, 120, load lock chambers 112A, 112B in the load lock apparatus 112, which may be adapted to open and close when placing or extracting substrates to and from the various chambers. Slit valves may be of any suitable conventional construction, such as L-motion slit valves.

The motion of the various arm components of the multi-arm robot 103 may be controlled by suitable commands to a drive assembly (not shown) containing a plurality of drive motors of the multi-arm robot 103 as commanded from a controller 125. Signals from the controller 125 may cause motion of the various components of the multi-arm robot 103. Suitable feedback mechanisms may be provided for one or more of the components by various sensors, such as position encoders, or the like.

The multi-arm robot 103 may include arms rotatable about a shoulder axis, which may be approximately centrally located in the respective transfer chamber 102. The multi-arm robot 103 may include a base that is adapted to be attached to a housing wall (e.g., a floor) forming a lower portion of the respective transfer chamber 102. However, the multi-arm robot 103 may be attached to a ceiling in some embodiments.

Additionally, the drive assembly of the multi-arm robot 103 may include Z-axis motion capability in some embodiments. In particular, the motor housing may be restrained from rotation relative to an outer casing by a motion restrictor. Motion restrictor may be two or more linear bearings or other type of bearing or slide mechanisms that function to constrain rotation of the motor housing relative to the outer casing, yet allow Z-axis (vertical) motion of the motor housing and connected arms along the vertical direction.

The vertical motion may be provided by a vertical motor. Rotation of the vertical motor may operate to rotate a lead screw in a receiver coupled to or integral with motor housing. This rotation may vertically translate the motor housing, and, thus, the arms, one or more attached end effectors, and the substrates supported thereon. A suitable seal may seal between the motor housing and the base thereby accommodating the vertical motion and retaining the vacuum within the transfer chambers 102.

FIG. 1B is a schematic diagram of another example embodiment of electronic device processing system 100B according to embodiments of the present invention. Electronic device processing system 100B may include a mainframe including a first mainframe 101 having housing walls defining a first transfer chamber 102. A first multi-arm robot 103 (shown as a dotted circle) may be at least partially housed within the first transfer chamber 102. A first multi-arm robot 103 may be configured and adapted to place or extract substrates (e.g., silicon wafers which may have a pattern therein) to and from destinations via operation of the arms of the first multi-arm robot 103.

First multi-arm robot 103 may be any suitable type of off-axis robot adapted to service the various twin chambers coupled to and accessible from the first transfer chamber 102, such as the robot disclosed in PCT Pub. No. WO2010090983, for example, which is hereby incorporated by reference herein. Other robots, such as off-axis robots, may be used. An off-axis robot is any robot configuration that can operate to extend an end effector other than radially towards or away from a shoulder rotational axis of the robot, which is generally centered at the center of a chamber, such as the first transfer chamber 102. The transfer chamber 102 in the depicted embodiment may be generally square or slightly rectangular in shape and may include a first facet 102A, second facet 102B which may be opposite the first facet 102A, a third facet 102C, and a fourth facet 102D which may be opposite the third facet 102C. The first multi-arm robot 103 may be preferably adept at transferring and/or retracting dual substrates at a same time into the chamber sets (side-by-side chambers). The first facet 102A, second facet 102B, third facet 102C, and fourth facet 102D may be generally planar and entryways into the chamber sets may lie along the respective facets 102A-102D.

Electronic device processing system 100B may include a second mainframe 104 also having housing walls defining a second transfer chamber 106. A second multi-arm robot 107 (shown as a dotted circle) may be at least partially housed within the second transfer chamber 106. First and second multi-arm robot 103, 107 may be substantially the same or different, but each may be configured and operable to service off-axis process chambers, as shown. Most preferably, each are adapted and configured to service twined chambers (those oriented in a side-by-side configuration as pairs or sets, as shown).

The destinations for the first multi-arm robot 103 may be a first process chamber set 108A, 108B, coupled to the first facet 102A. First process chamber set 108A, 108B may be configured and operable to carry out a pre-clean or a metal or metal oxide removal process, such as a metal oxide reduction process on the substrates delivered thereto. The metal or metal oxide removal process may be as described in US Pub. No. 2009/0111280; and 2012/0289049; and U.S. Pat. Nos. 7,972,469; 7,658,802; 6,946,401; 6,734,102; and 6,579,730, for example, which are hereby incorporated by reference herein. One or more other pre-clean processes may be carried out therein, which are precursor processes to a cobalt deposition process. The destinations for the first multi-arm robot 103 may also be a second process chamber set 110A, 110B, which are shown generally opposed from the first process chamber set 108A, 108B in the depicted embodiment. The second process chamber set 110A, 110B may be coupled to the second facet 102B and may be configured and adapted to carry out high-temperature reducing anneal process on the substrates in some embodiments. The high-temperature reducing anneal processes may be as described in US Pub. No. 2012/0252207; and U.S. Pat. Nos. 8,110,489, and 7,109,111, for example, which are hereby incorporated by reference herein. The annealing may take place at a temperature of about 400° C. or more.

As previously described, substrates may be received from a factory interface 114, and also exit the first transfer chamber 102, to the factory interface 114, through a load lock apparatus 112. The load lock apparatus 112 may include chambers at multiple vertical levels in some embodiments. For example, in some embodiments, each vertical level may include side-by-side chambers. Some chambers may be located at first level and others at a second level at a different level than the first level (either above or below). Side-by-side chambers may be at the same vertical level at the lower level, and other Side-by-side chambers at a same vertical level may be provided at the upper level.

For example, load lock chambers 112A, 112B included as load locks (e.g., single wafer load locks (SWLL)) may be provided at a lower vertical level in the load lock apparatus 112. The load lock chambers 112A, 112B (e.g., single wafer load locks (SWLL)) may each have a heating platform/apparatus to heat the substrate to greater than about 200° C., such that a degassing process may be carried out on incoming substrates before they are passed into the first transfer chamber 102 from the factory interface 114 as described in US as described in U.S. patent application Ser. No. 14/203,098 filed Mar. 10, 2014.

The load lock apparatus 112 may include second side-by-side chambers at an upper vertical level in the load lock apparatus 112, at a position above the lower level. In some embodiments, the load lock apparatus 112 includes a first chamber or chamber set adapted to carry out a degas process at a first level, and second chamber or chamber set adapted to carry out a cool-down process at second level thereof, wherein the first and second levels are different levels. In other embodiments, second side-by-side chambers in the load lock apparatus 112 may be used to carry out a pre-clean or oxide reduction process on the substrates, such as a metal oxide reduction process on the substrates as described in U.S. patent application Ser. No. 14/203,098 filed Mar. 10, 2014. Thus, in some embodiments, additional stations to accomplish a metal or metal oxide reduction process or other processes such as cool down on the substrates may be provided in the load lock apparatus 112 in addition to those provided at the first process chamber set 108A, 108B. The additional stations to accomplish a metal or metal oxide reduction process or other processes on the substrates may be provided in the load lock apparatus 112 in substitution to those provided at the first process chamber set 108A, 108B in some embodiments, such that second process chamber set 110A, 110B may be used for other processes, such as annealing, cooling, temporary storage, or the like.

The factory interface 114 may be any enclosure having one or more load ports 115 that are configured and adapted to receive one or more substrate carriers 116 (e.g., front opening unified pods or FOUPs) at a front face thereof. Factory interface 114 may include a suitable exchange robot 117 (shown dotted) of conventional construction within a chamber thereof. The exchange robot 117 may be configured and operational to extract substrates from the one or more substrate carriers 116 and feed the substrates into the one or more load lock chambers 112A, 112B (e.g., single wafer load locks (SWLL)), such as may be provided at a lower vertical level in the load lock apparatus 112.

The second mainframe 104 may be coupled to the first mainframe 101, such as by a pass-through apparatus 118. Pass-through apparatus 118 may include a first pass-through chamber 118A and a second pass-through chamber 118B adapted to pass substrates between the respective transfer chambers 102, 106. The pass-through apparatus 118 may be coupled to the fourth facet 102D of the first mainframe 101 and to a seventh facet 106C of the second mainframe 104. The second mainframe 104 may include multiple process chamber sets that are accessible and serviceable from the second transfer chamber 106 and multiple facets. For example, the second mainframe 104 may have a fifth facet 106A, a sixth facet 106B opposite the fifth facet 106A, a seventh facet 106C, and an eighth facet 106D opposite the seventh facet 106C. For example, the second mainframe 104 may have two or more process chamber sets coupled thereto, such as a first deposition process chamber set 120A, 120B, second deposition process chamber set 122A, 122B which may be opposite the first deposition process chamber set 120A, 120B, and a third deposition process chamber set 124A, 124B. Deposition process chamber sets 120A, 120B, 122A, 122B, and 124A, 124B may be coupled to respective fifth facet 106A, sixth facet 106B, and eighth facet 106D, and accessible from the second transfer chamber 106, as shown. Other configurations may be used. The second multi-arm robot 107 may be operational to place and remove substrates from the deposition process chamber sets 120A, 120B, 122A, 122B, and 124A, 124B. Process chamber sets 120A, 120B, 122A, 122B, and 124A, 124B may be configured and adapted to carry out any number of deposition process steps on substrates received thereat.

For example, each of the deposition process chambers 120A, 120B, 122A, 122B, and 124A, 124B may carry out a cobalt (Co) chemical vapor deposition (CVD) process. Co deposition CVD processes are taught in US Pub. No. 2012/0252207, for example, which is hereby incorporated by reference herein. Other processes may also be carried out therein, such as cobalt plasma vapor deposition (cobalt PVD). In some embodiments, the transfer chambers 102, 106 may be operated at a vacuum. In others, especially the second transfer chamber 106 may receive an insert gas therein, such as Argon (Ar). argon gas may be provided by any suitable conventional gas delivery system.

Substrates as used herein shall mean articles used to make electronic devices or circuit components, such as silica-containing wafers, patterned wafers, or the like.

In some embodiments, the substrates may have previously undergone a PVD deposition process (e.g., a PVD Co deposition and/or a PVD CO flash process). The PVD CO flash process may function to provide a thin seed layer. In some embodiments, a PVD process may be carried out before the CVD cobalt deposition process, and may also be carried out after the CVD cobalt deposition process, as well. In some embodiments, the PVD process may be carried out in an entirely different tool that is separate from the electronic device processing system 100B. However, in some embodiments, the PVD cobalt deposition may take place at one or more of the deposition process chambers sets 120A, 120B, 122A, 122B, or 124A, 124B.

For example, at least one of the first deposition process chamber set 120A, 120B, the second deposition process chamber set 122A, 122B, and the third deposition process chamber set 124A, 124B may be adapted to carry out a PVD cobalt process on the substrates. However, in one embodiment, all three of the first deposition process chamber set 120A, 120B, the second deposition process chamber set 122A, 122B, and the third deposition process chamber set 124A, 124B may be adapted to carry out a cobalt CVD process.

Each of the transfer chambers 102, 106 may include slit valves at their ingress/egress to the various process chambers 108A, 108B, 110A, 10B, 120A, 120B, 122A, 122B, 124A, 124B, load lock chambers 112A, 112B in the load lock apparatus 112, and pass-through chambers 118A, 118B in the pass-through apparatus 118, which may be adapted to open and close when placing or extracting substrates to and from the various chambers. Slit valves may be of any suitable conventional construction, such as L-motion slit valves.

The motion of the various arm components of the multi-arm robots 103, 107 may be controlled by suitable commands to a drive assembly (not shown) containing a plurality of drive motors of the multi-arm robots 103, 107 as commanded from a controller 125. Signals from the controller 125 may cause motion of the various components of the multi-arm robots 103, 107. Suitable feedback mechanisms may be provided for one or more of the components by various sensors, such as position encoders, or the like.

The multi-arm robots 103, 107 may include arms rotatable about a shoulder axis, which may be approximately centrally located in the respective transfer chambers 102, 106. The multi-arm robots 103, 107 may include a base that is adapted to be attached to a housing wall (e.g., a floor) forming a lower portion of the respective transfer chamber 102, 106. However, the multi-arm robots 103, 107 may be attached to a ceiling in some embodiments. The multi-arm robot 103, 107 may be a dual SCARA robot or other type of dual robot adapted to service twin chambers (e.g., side-by-side chambers).

In the depicted embodiment, the twin chambers are chambers that have a common facet (e.g., connection surface) that are generally positioned in a side-by-side relationship, and that have generally co-parallel connection surfaces. The rotation of the arm components of the multi-arm robot 103, 107 may be provided by any suitable drive motor, such as a conventional variable reluctance or permanent magnet electric motor. Arms may be adapted to be rotated in an X-Y plane relative to the base. Any suitable number of arm components and end effectors adapted to carry the substrates may be used. Robots useful for transferring substrates within the transfer chambers may be as described in PCT Publication WO2010080983A2 and US Pub. No. 20130115028A1, which are hereby incorporated by reference herein. Other types of robots may be used.

Additionally, the drive assembly of the multi-arm robot 103, 107 may include Z-axis motion capability in some embodiments. In particular, the motor housing may be restrained from rotation relative to an outer casing by a motion restrictor. Motion restrictor may be two or more linear bearings or other type of bearing or slide mechanisms that function to constrain rotation of the motor housing relative to the outer casing, yet allow Z-axis (vertical) motion of the motor housing and connected arms along the vertical direction.

The vertical motion may be provided by a vertical motor. Rotation of the vertical motor may operate to rotate a lead screw in a receiver coupled to or integral with motor housing. This rotation may vertically translate the motor housing, and, thus, the arms, one or more attached end effectors, and the substrates supported thereon. A suitable seal may seal between the motor housing and the base thereby accommodating the vertical motion and retaining the vacuum within the transfer chambers 102, 106. Although shown as rectangular transfer chambers 102, 106, it should be recognized that other polygonal mainframe shapes may be used, such as pentagonal, hexagonal, heptagonal, octagonal, and the like.

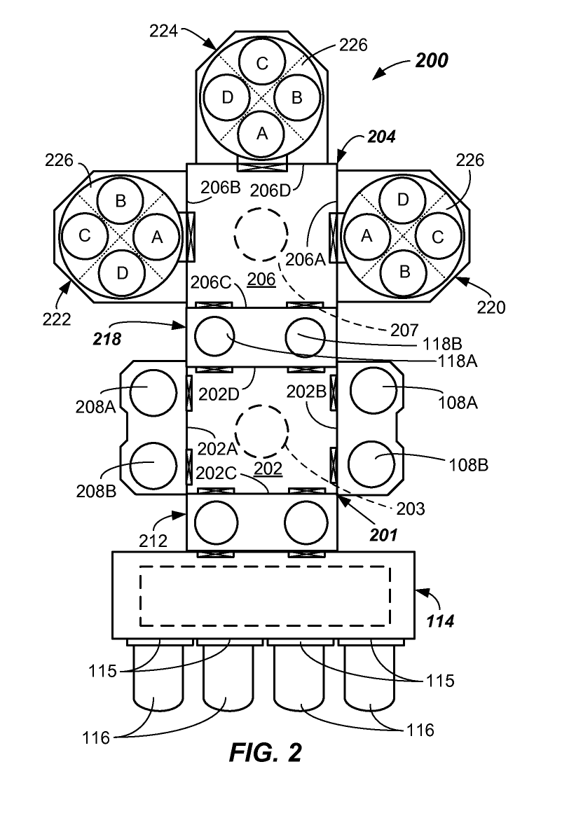

FIG. 2 illustrates an alternative embodiment of an electronic device processing system 200. The electronic device processing system 200 includes a mainframe including a first mainframe 201 and a second mainframe 204. The first mainframe 201 may include one or more facets and a first process chamber (e.g., process chamber 208A) coupled to one of the facets, the first process chamber being configured and adapted to carry out a process on the substrates, such as a metal or metal oxide reduction process, as discussed above. The second mainframe 204 may include one or more facets that may include one or more deposition process chambers coupled thereto, wherein the one or more deposition process chambers may be configured and adapted to carry out a cobalt chemical vapor deposition process on substrates. In one or more embodiments, a PVD cobalt deposition process may take place within one or more of the deposition process chambers. In some embodiments, one or more, two or more, or even three of the deposition process chambers may embodied as carousels, to be described more thoroughly below.

In more detail, the depicted electronic device processing system 200 includes, as in the previous embodiment, a first mainframe 201 having a first transfer chamber 202, and multiple facets such as a first facet 202A, a second facet 202B opposite the first facet 202A, a third facet 202C, and a fourth facet 202D opposite the third facet 202C. The mainframe 201 may include four sides and have a generally square or slightly rectangular shape as in the previous embodiment. Other polygonal mainframe shapes, such as pentagonal, hexagonal, heptagonal, octagonal, and the like, may be used. A first robot 203 is at least partially housed in the transfer chamber 202 and is operational to exchange substrates to and from the various chambers coupled to and accessible from the first transfer chamber 202.

The electronic device processing system 200 may include a first process chamber set 208A, 208B coupled to the first facet 202A. The first process chamber set 208A, 208B may be configured and adapted to carry out a process on the substrates, such as a metal or metal oxide reduction process. Metal oxide reduction process may be as described above. A load lock apparatus 212 may be coupled to the third facet 202C, and a pass-through apparatus 218 may be coupled to the fourth facet 202D. Other arrangements are possible.

A second mainframe 204 having a second transfer chamber 206 may be coupled to the pass-through apparatus 218. The second mainframe 204 may include multiple facets, such a fifth facet 206A, a sixth facet 206B opposite the fifth facet 206A, a seventh facet 206C, and an eighth facet 206D opposite the seventh facet 206C. Other configurations are possible. One or more of the facets (e.g., facets 206A, 206B, 206D) may include a deposition process chamber set coupled thereto, such that the deposition process chamber sets 220, 222, 224 may be accessed by the robot 207.

In some embodiments, at least a first deposition process chamber set 220 and possibly a second deposition process chamber set 222 may be coupled to at least one of the fifth facet 206A, sixth facet 206B, or eighth facet 206D and may be configured and adapted to carry out a cobalt chemical vapor deposition process on substrates, and wherein the seventh facet 206C may be coupled to the pass-through apparatus 218, as shown. In one or more embodiments, a PVD cobalt deposition process may take place within at least one of the deposition process chamber sets 220, 222, or 224. Other configurations of the deposition process chamber sets 220, 222, or 224 are possible.

In some embodiments, one or more, two or more, or even three of the deposition process chamber sets 220, 222, or 224 may embodied as carousels, such as shown in FIG. 2. For example, at least the first deposition process chamber set 220 and the second deposition process chamber set 222 may be provided as carousels. In the depicted embodiment, all three of the first deposition process chamber set 220, second deposition process chamber set 222, and third deposition process chamber set 224 are embodied as carousels coupled to the fifth, sixth, and eighth facets, respectively. However, more or less numbers of facets and coupled carousels are possible.

In particular, the carousels may include a plurality of positions (A, B, C, D) on a rotating carousel member 226 (e.g., a susceptor) that are adapted to receive substrates thereat. The stations may number two, three, four or more. Four stations may be optimal for throughput considerations. The rotating carousel member 226 rotates under the operation of rotational motor (not shown) and is loaded adjacent to the slit valve at station A, as shown. Then the rotating carousel member 226 is rotated to various stations where processing takes place. Cobalt CVD may take place in some embodiments. For example, station B and C may be cobalt CVD deposition stations. Station D may be an annealing station in some embodiments wherein the substrate after undergoing one or more CVD deposition phases, may be annealed at a temperature of about 400° C. or more. In the electronic device processing system 200 shown, each deposition chamber set 220, 222, 224 embodied as a carousel may include at least four stations (A, B, C, and D), which comprise a loading station (station A), two cobalt CVD stations (stations B and C) and one annealing station (station D). Other numbers and types of stations may be provided. Each deposition chamber set 220, 222, 224 may be operated at a suitable vacuum level and injector heads may be positioned at stations B and C for depositing a cobalt-containing gas, for example.

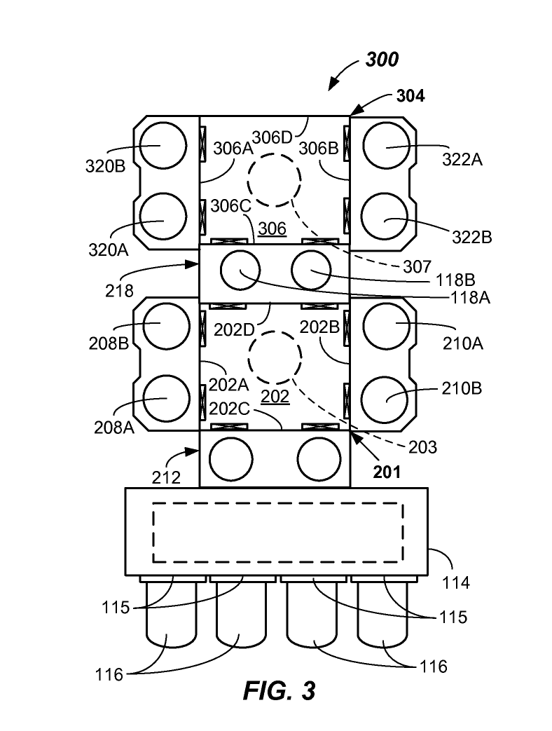

FIG. 3 illustrates yet another alternative embodiment of an electronic device processing system 300. The system 300 includes, as in the previous embodiments, a first mainframe 201 including a first transfer chamber 202, and a plurality of facets, such as a first facet 202A, a second facet 202B opposite the first facet 202A, a third facet 202C, and a fourth facet 202D opposite the third facet 202C. The mainframe 201 may include four sides and have a generally square or slightly rectangular shape. Other shapes and numbers of facets may be used, such as octagonal, hexagonal, and the like. A first robot 203 may be at least partially housed in the transfer chamber 202 and is operational to exchange substrates to and from the various chambers coupled to and accessible from the first transfer chamber 202.

The electronic device processing system 300 also includes process chamber sets coupled to at least some of the facets, such as a first process chamber set 208A, 208B coupled to the first facet 202A. The first process chamber set 208A, 208B may be configured and adapted to carry out a pre-cleaning process on the substrates, such as a metal reduction or metal oxide reduction process. Metal oxide reduction process may be as described above. A load lock apparatus 212 may be coupled to the third facet 202C, and a pass-through apparatus 218 may be coupled to the fourth facet 202D. Load lock apparatus 212 may also be as otherwise described herein.

A second mainframe 304 having a second transfer chamber 306 may be coupled to the pass-through apparatus 218. The second mainframe 304 may include a plurality of facets, such as a fifth facet 306A, a sixth facet 306B opposite the fifth facet 206A, and a seventh facet 306C. One or more of the facets 306A and 306B may each include a deposition process chamber or deposition chamber set coupled thereto. For example, deposition chamber sets 320A, 320B and 322A, 322B may be coupled thereto. The facets 306A and 306B may each include a deposition process chamber set 320A, 320B and 322A, 322B coupled thereto, such that the deposition process chamber sets 320A, 320B and 322A, 322B may be accessed by the robot 307. Each of the deposition process chamber sets 320A, 320B and 322A, 322B may be configured and adapted to carry out a process on the substrates, such as a cobalt chemical vapor deposition (CVD) process. The second process chamber set 210A, 210B coupled to the first transfer chamber 202 may be adapted to carry out a high-temperature anneal process as described above. The remainder of the electronic device processing system 300 may be the same as described for the FIG. 2 embodiment.

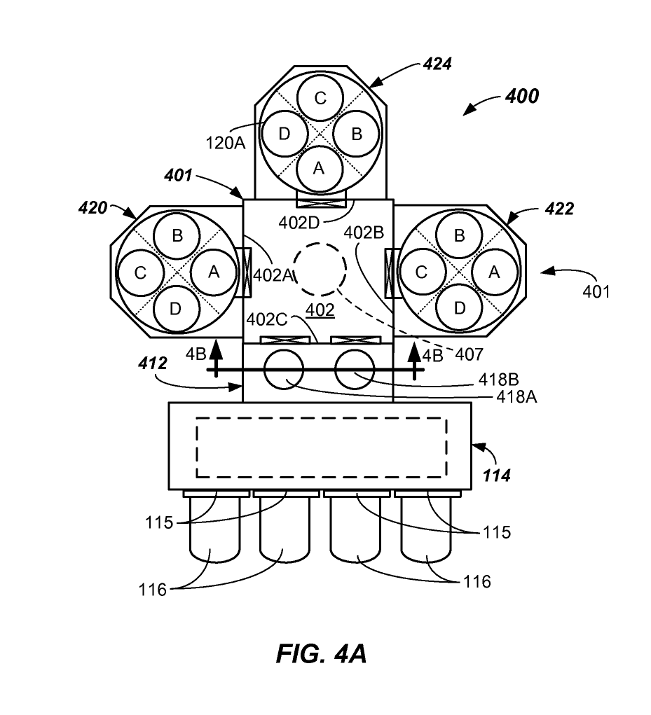

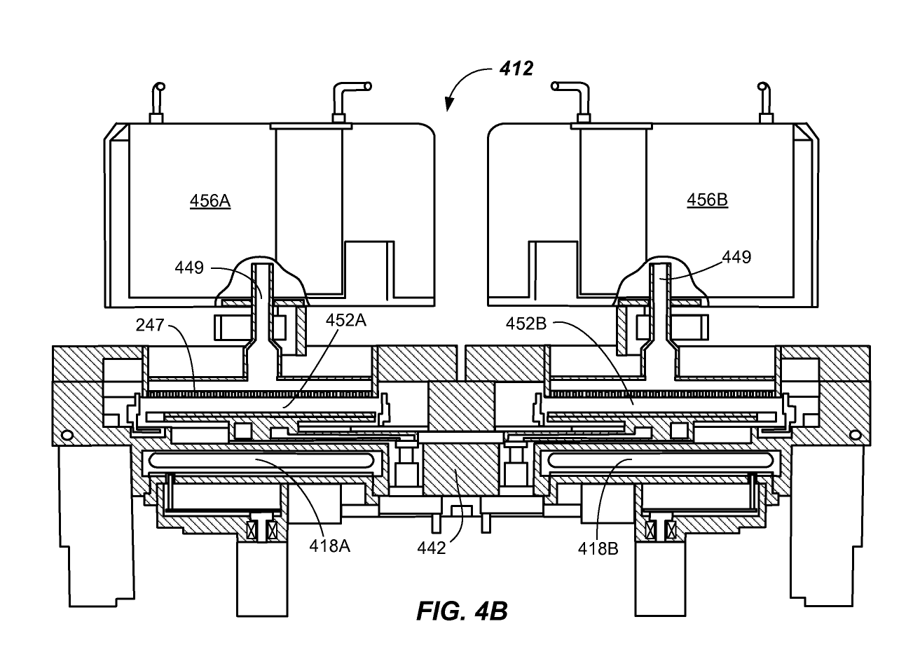

FIGS. 4A and 4B illustrates yet another alternative embodiment of an electronic device processing system 400. This embodiment of electronic device processing system 400 includes only a first mainframe 401 defining a first transfer chamber 402. Mainframe 401 may have multiple facets, as shown. Multiple facets may include a first facet 402A, a second facet 402B opposite the first facet 402A, a third facet 402C, and a fourth facet 402D opposite the third facet 402C. The mainframe 401 may have four sides and four right angled corners and have a generally square or slightly rectangular shape. However, other polygonal mainframe shapes, such as pentagonal, hexagonal, heptagonal, octagonal, and the like, may be used. A robot 407 may be at least partially housed in the transfer chamber 402, and is operational to exchange substrates to and from the various chambers coupled to and accessible from the transfer chamber 402.

The electronic device processing system 400 may also include one or more deposition process chambers sets 420, 422, 424 embodied as carousels coupled to facets thereof that are adapted to carry out processing. In particular, the electronic device processing system 400 may include a first deposition process chamber set 420 comprising a carousel coupled to the first facet 402A, and a second deposition process chamber set 422 comprising a carousel coupled to the second facet 402B. Second facet may be opposite from the first facet 402A. A load lock apparatus 412 may be coupled to the third facet 402C. A third deposition process chamber set 424 comprising a carousel may be coupled to the fourth facet 402D, which may be located opposite the load lock apparatus 412. Other configurations may be used.

One or more of the first, second, and third deposition process chamber sets 420, 422, 424 may be configured and adapted to carry out a process on the substrates, such as a cobalt chemical vapor deposition (CVD) process. In some embodiments, at least some of the stations or carousels of the first, second, and third process chamber sets 420, 422, 424 may be adapted to carry out a high-temperature anneal process. The high temperature annealing process may take place at one of the process chamber sets 420, 422, 424 only, or may be integrated into each of the process chamber sets 420, 422, 424. In this integrated embodiment, each of the process chamber sets 420, 422, 424 may include one or more CVD Cobalt deposition stations and one or more annealing stations therein.

FIG. 4B illustrates a representative cross-section of the load lock apparatus 412 taken along section line 4B-4B of FIG. 4A and illustrating load lock process chambers 452A, 452B, load lock pass-through chambers 418A, 418B, and other components. Additional description of the load lock apparatus 412 is found in U.S. patent application Ser. No. 14/203,098 filed Mar. 10, 2014.

Process load lock apparatus 414 includes a common body 442 having slit valves operable with load lock chambers 418A, 418B and the load lock process chambers 452A, 452B. Both the load lock chambers 418A, 418B and the load lock process chambers 452A, 452B may accessible from the transfer chamber 402 by robot 407. Exits from the load lock chambers 418A, 418B may be provided on the other side and accessed from the factory interface 114. In the depicted embodiment, the load lock process chambers 452A, 452B may be located directly above the load lock chambers 418A, 418B. As shown in FIG. 4B, a plasma source 456A, 456B may be coupled to each of the process chambers 452A, 452B. In the depicted embodiments, a gas (e.g., H₂) may be supplied at inlets to the remote plasma sources 456A, 456B. Distribution channel 449 couple the respective load lock process chambers 452A, 452B to the remote plasma sources 456A, 456B.

A suitable vacuum pump and control valve may be provided underneath the common body 442 and may be used to generate a suitable vacuum within the various process chambers 452A, 452B for the particular process being carried out therein. Other control valves and vacuum pumps may be used. In the embodiment shown in FIG. 4B, the lower load lock chambers 418A, 418B of the load lock apparatus 412 may function as load locks enabling the flow of substrates between the transfer chamber 402 and the factory interface 114. Process chambers 452A, 452B may be configured and operable to carry out an auxiliary process on the substrates, such as a metal or metal oxide reduction process on the substrates delivered thereto. The metal oxide reduction process may be as described above.

In some embodiments, one or more of the process chambers may be used to carry out an annealing process, such as at process chamber set 452A, 452B that is coupled to the transfer chamber 402. In particular, the process chamber set 452A, 452B may optionally be adapted to carry out a high-temperature anneal process as described above. The robot 407 may be any suitable robot adapted to access off-axis chambers, such as those described above.

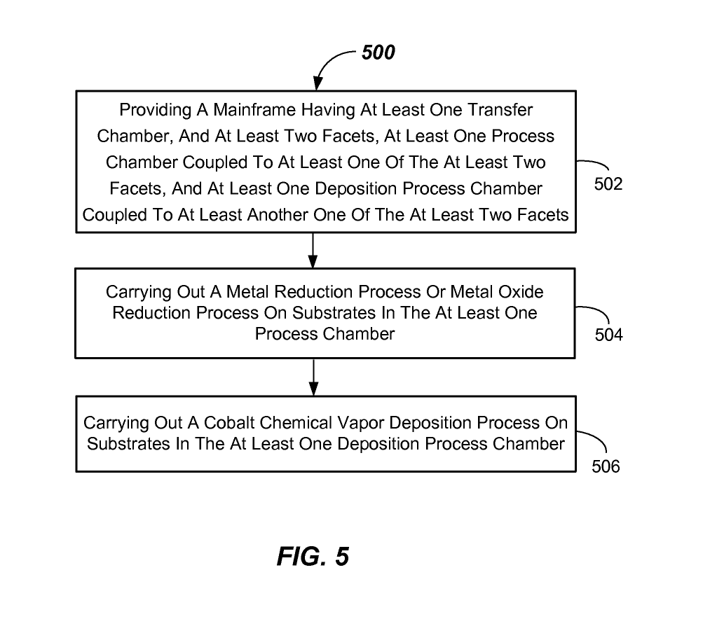

A first method of processing substrates within an electronic device processing system (e.g., systems 100A, 100B, 200, 300, 400) will be described with reference to FIG. 5 herein. The method 500 includes, in 502, providing a mainframe having at least one transfer chamber (e.g., transfer chamber 102, 106, 202, 206, 306, 402) and at least two facets, at least one process chamber (e.g., process chamber 108, 108A, 108B, 110, 110A, 110B, 208A, 208B, 210A, 210B, 452A, 542B) coupled to at least one of the at least two facets, and at least one deposition process chamber (e.g., deposition process chamber 120, 120A, 120B, 122A, 122B, 420, 422, 424) coupled to at least another one of the at least two facets.

The method 500 includes, in 504, carrying out a metal reduction process or metal oxide reduction process (e.g., a copper oxide removal process) on substrates in the at least one process chamber.

The method 500 includes, in 506, carrying out a cobalt chemical vapor deposition process on substrates in the at least one deposition process chamber.

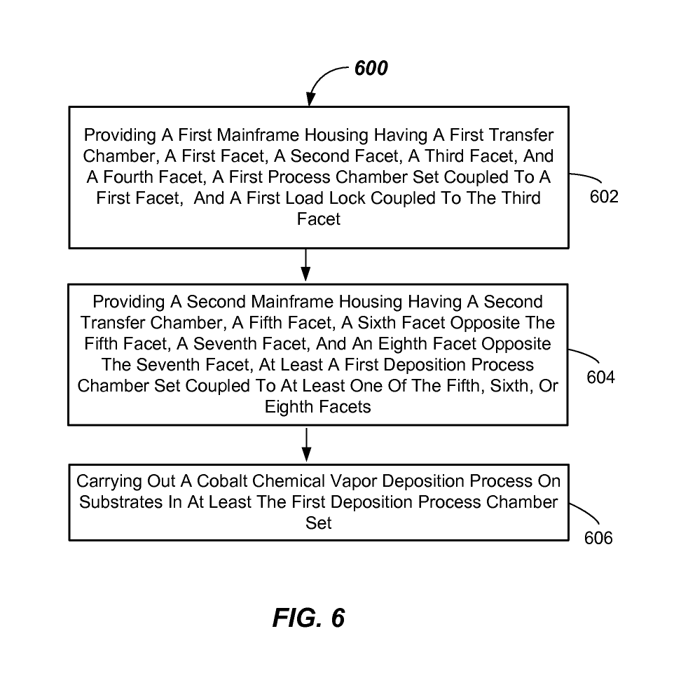

Another method of processing substrates within an electronic device processing system (e.g., systems 100A, 100B, 200, 300) will be described with reference to FIG. 6 herein. The method 600 includes, in 602, providing a first mainframe (e.g., mainframe 101, 201) having a first transfer chamber (e.g., first transfer chamber 102, 202), a first facet (e.g., 102A, 202A), a second facet (e.g., 102B, 202B), that may be opposite the first facet, a third facet (e.g., 102C, 202C), and a fourth facet (e.g., 102D, 202D) that may be opposite the third facet, and a first process chamber set (e.g., 120A, 120B, 220) coupled to a first facet. A second process chamber set (e.g., 122A, 122B, 222) may be coupled to the second facet, and a first load lock (e.g., 112, 212) may be coupled to the third facet (e.g., third facet 102C, 202C).

The method 600 includes, in 604, providing a second mainframe (e.g., second mainframe 104, 204, 304) having a second transfer chamber (e.g., 106, 206, 306), a fifth facet (e.g., 106A, 206A, 306A), a sixth facet (e.g., 106B, 206B, 306B), opposite the fifth facet, a seventh facet (e.g., 106C, 206C, 306C), and an eighth facet (e.g., 106D, 206D, 306D) opposite the seventh facet, at least a first deposition process chamber set (e.g., 120A, 120B or 220, 320A, 320B), coupled to at least one of the fifth, sixth, or eighth facets.

The method 600 includes, in 606, carrying out a cobalt chemical vapor deposition process on substrates in at least the first deposition process chamber set (e.g., in 120A, 120B or in 220 or in 320A, 320B, for example). In some embodiments, cobalt chemical vapor deposition process on substrates may be carried out in a first and second deposition process chamber set (e.g., in 120A, 120B and 122A, 122B or in 220 and 222, or in 320A, 320B and 322A, 322B). In yet other embodiments, cobalt chemical vapor deposition process on substrates may be carried out in three deposition process chamber sets (e.g., in 120A, 120B, 122A, 122B, and 124A, 124C as shown in FIG. 1B or in 220, 222, 224 as shown in FIG. 2) that are coupled to and accessible from the second transfer chamber (e.g., 106, 206).

In some embodiments, such as the embodiment of FIG. 2, one or more, two or more, or even three carousels may include the deposition chamber sets 220, 222, and 224 and may be coupled to, and accessible from, the second transfer chamber 206. For example, in one or more embodiments, first, second, and third deposition process chamber sets 220, 222, and 224 may be coupled to the respective fifth facet 206A, sixth facet 206B, and eighth facet 206D.

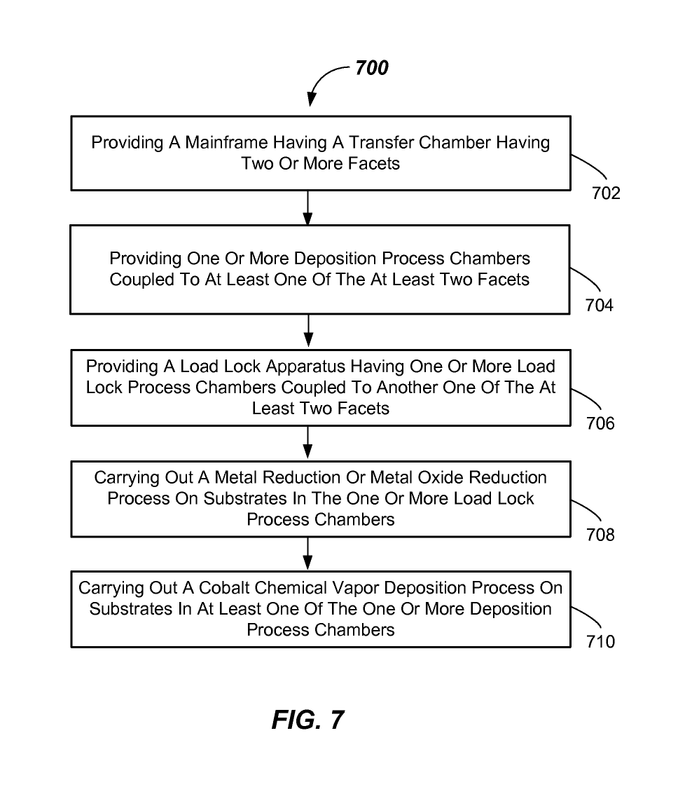

In another method embodiment described with reference to FIGS. 4A and 4B and FIG. 7, a method of processing substrates within an electronic device processing system (e.g., electronic device processing system 400) is provided. The method 700 includes, in 702, providing a mainframe (e.g., mainframe 401) having a transfer chamber (e.g., transfer chamber 402), and at least two facets, such as a first facet (e.g., 402A), a second facet (e.g., 402B) that may be opposite the first facet, a third facet (e.g., 402C), and a fourth facet (e.g., 402D) that may be opposite the third facet. The facets may form a general rectangular or square shape in horizontal cross-section. However, more facets may be provided, such as in pentagonal, hexagonal, heptagonal, and octagonal mainframe shapes.

The method 700 includes, in 704, providing one or more deposition process chamber (e.g., in first, second, and third deposition process chamber sets 420, 422, 424) coupled to at least one of the at least two facets, such as to the first facet, the second facet, or the fourth facet.

The method 700 includes, in 706, providing a load lock apparatus (e.g., 412) having one or more load lock process chamber (e.g., 418A, 418B), the load lock apparatus coupled to another one of the at least two facets, such as the third facet (e.g., 402C). The load lock apparatus may also be coupled to a factory interface (e.g., 114).

The method 700 further includes, in 708, carrying out a metal reduction or metal oxide reduction process on substrates in the one or more load lock process chamber, and, in 710, carrying out a cobalt chemical vapor deposition process on substrates in at least one of the deposition process chambers.

The foregoing description discloses only example embodiments of the invention. Modifications of the above-disclosed apparatus, systems and methods which fall within the scope of the invention will be readily apparent to those of ordinary skill in the art. Accordingly, while the present invention has been disclosed in connection with example embodiments, it should be understood that other embodiments may fall within the scope of the invention, as defined by the following claims.

The invention claimed is:

1. An electronic device processing system, comprising:
a mainframe having at least one transfer chamber, and at least two facets;
a first process chamber coupled to at least one of the at least two facets and adapted to carry out a metal reduction process or metal oxide reduction process on substrates; and
at least one deposition process chamber coupled to another one of the at least two facets and adapted to carry out a cobalt chemical vapor deposition process on substrates.

2. The electronic device processing system of claim 1, wherein the at least one deposition process chamber comprises at least one deposition process chamber set adapted to carry out the cobalt chemical vapor deposition process.

3. The electronic device processing system of claim 1, comprising a second process chamber coupled to another facet and adapted to carry out an annealing process on the substrates.

4. The electronic device processing system of claim 1, comprising:
a first mainframe having a first transfer chamber and a first plurality of facets;
the first process chamber coupled to one of the plurality of facets and adapted to carry out the metal reduction process or a metal oxide reduction process on substrates;
a load lock apparatus coupled to one of the first plurality of facets;
a pass-through apparatus coupled to one of the first plurality of facets;
a second mainframe having a second transfer chamber, and a second plurality of facets; and
the at least one deposition process chamber coupled to one of the second plurality of facets and adapted to carry out the cobalt chemical vapor deposition process on substrates.

5. The electronic device processing system of claim 1, wherein at least one of the deposition process chambers is adapted to carry out a plasma vapor deposition process on substrates.

6. The electronic device processing system of claim 1, comprising a load lock apparatus coupled to at least another facet of the at least two facets, the load lock apparatus adapted to carry out a metal reduction or metal oxide reduction process on substrates.

7. The electronic device processing system of claim 1, comprising:
a first mainframe having a first transfer chamber, a first facet, a second facet, a third facet, and a fourth facet;
a first process chamber set coupled to the first facet and adapted to carry out a metal reduction or metal oxide reduction process on substrates;
a load lock apparatus coupled to the third facet;
a pass-through apparatus coupled to the fourth facet;
a second mainframe having a second transfer chamber, a fifth facet, a sixth facet, a seventh facet, and an eighth facet; and
at least one deposition process chamber set coupled to at least one of the fifth, sixth or eighth facets and adapted to carry out a cobalt chemical vapor deposition process on substrates.

8. The electronic device processing system of claim 7, comprising a second process chamber set coupled to the second facet and adapted to carry out an annealing process on the substrates.

9. The electronic device processing system of claim 8 wherein an annealing temperature of the annealing process is above 400° C.

10. The electronic device processing system of claim 7 comprising:
a first deposition process chamber set is coupled to the fifth facet;
a second deposition process chamber set is coupled to the sixth facet; and
and a third deposition process chamber set is coupled to the eighth facet; and
each of the first deposition process chamber set, second deposition process chamber set, and third deposition process chamber set are adapted to carry out a cobalt chemical vapor deposition process on substrates.

11. The electronic device processing system of claim 7 wherein at least one other deposition process chamber set is adapted to carry out a plasma vapor deposition process on substrates.

12. The electronic device processing system of claim 7 wherein at least one of the first transfer chamber and the second transfer chamber are provided with an inert gas.

13. The electronic device processing system of claim 12 wherein the inert gas comprises argon.

14. The electronic device processing system of claim 7 wherein at least one of the at least one deposition process chamber set are included in a carousel.

15. A method of processing substrates within an electronic device processing system, comprising:
providing a mainframe having at least one transfer chamber and at least two facets, at least one process chamber coupled to at least one of the at least two facets, and at least one deposition process chamber coupled to at least another one of the at least two facets;
carrying out a metal reduction process or metal oxide reduction process on substrates in the at least one process chamber; and
carrying out a cobalt chemical vapor deposition process on substrates in the at least one deposition process chamber.

16. The method of claim 15, comprising:
providing a first mainframe having a first transfer chamber, a first facet, a second facet, a third facet, and a fourth facet, a first process chamber set coupled to the first facet, and a first load lock coupled to the third facet; and
providing a second mainframe having a second transfer chamber, a fifth facet, a sixth facet, a seventh facet, and an eighth facet, and the at least one deposition process chamber set coupled to at least two of the fifth, sixth, or eighth facets.

17. The method of claim 15, comprising:
carrying out an annealing process on substrates in another one of the at least one process chamber.

18. An electronic device processing system, comprising:
a mainframe having a transfer chamber and at least two facets;
at least one deposition process chamber coupled to at least one of the at least two facets and adapted to carry out a cobalt chemical vapor deposition process on substrates; and
a load lock apparatus coupled to at least another facet of the at least two facets, the load lock apparatus adapted to carry out a metal reduction or metal oxide reduction process on substrates.

19. The electronic device processing system of claim 18 wherein the at least one deposition process chamber is included in a carousel.

20. A method of processing substrates within an electronic device processing system, comprising:
providing a mainframe having a transfer chamber and at least two facets;
providing one or more deposition process chambers coupled to at least one or the at least two facets;
providing a load lock apparatus having one or more load lock process chambers coupled to another one of the at least two facets;
carrying out a metal reduction or metal oxide reduction process on substrates in the one or more load lock process chamber; and
carrying out a cobalt chemical vapor deposition process on substrates in at least one of the one or more deposition process chambers.
